(19) United States
(12) Patent Application Publication
(10) Pub. No.: US 2014/0332181 A1
(43) Pub. Date: Nov. 13, 2014

(54) AIR DUCT

(71) Applicant: Hon Hai Precision Industry Co., Ltd., New Taipei (TW)

(72) Inventor: HSUAN-I LIN, New Taipei (TW)

(73) Assignee: HON HAI PRECISION INDUSTRY CO., LTD., New Taipei (TW)

(21) Appl. No.: 14/103,856

(22) Filed: Dec. 12, 2013

(30) Foreign Application Priority Data
May 8, 2013 (TW) 102116440

(51) Int. Cl. H05K 7/20

(52) U.S. Cl. CPC H05K 7/20145
USPC 165/80.2; 165/96

(57) ABSTRACT

An air duct includes a first duct. The first duct includes a first top board, two first sidewalls connected to opposite sides of the first top board, and a side cover. One of the first sidewalls defines an cutout. The side cover is rotatably connected to the first sidewall to cover or open the cutout.

### BACKGROUND

1. Technical Field

The present disclosure relates to an air duct.

2. Description of Related Art

Air ducts for a central processing unit often define an opening in a sidewall to accommodate an electronic element mounted on a motherboard. However, when the electronic element does not need to be accommodated in the opening, air leaks through the opening.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an air duct, wherein the air duct includes a board.

FIG. 2 is an assembled, isometric view of FIG. 1.

FIG. 3 is a cross-sectional view of FIG. 2, taken along the line III-III.

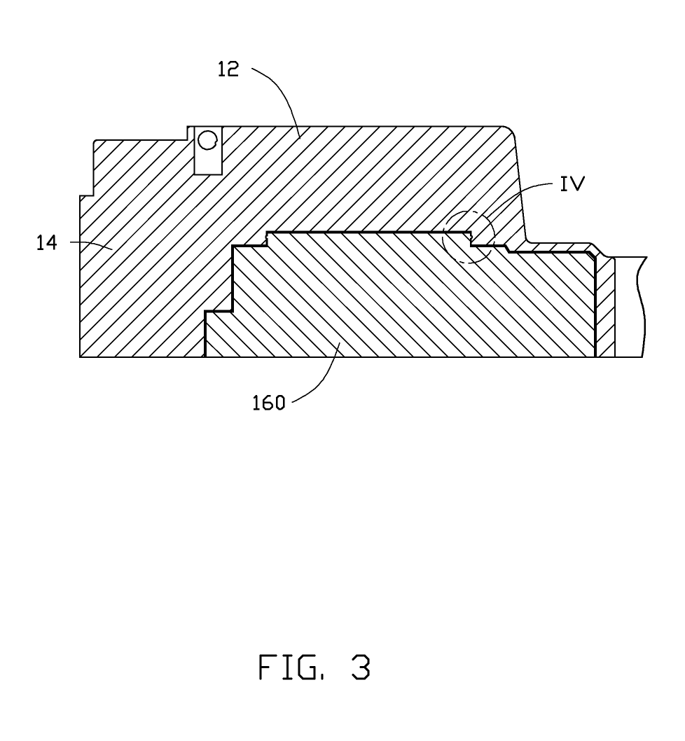

FIG. 4 is an enlarged view of the circled portion IV of FIG. 3.

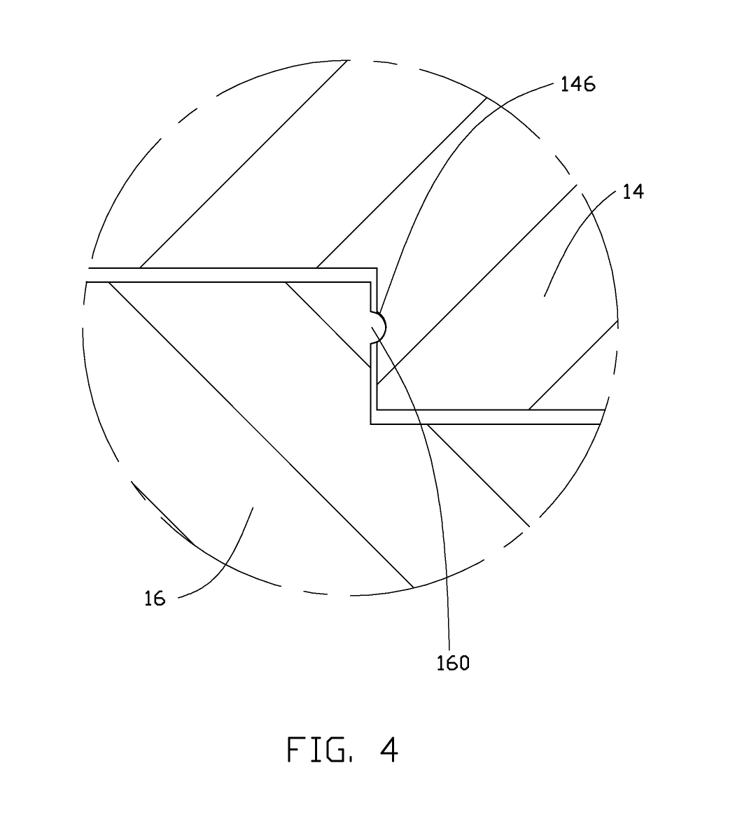

FIG. 5 is an assembled, isometric view of the air duct of FIG. 2, together with electronic elements.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

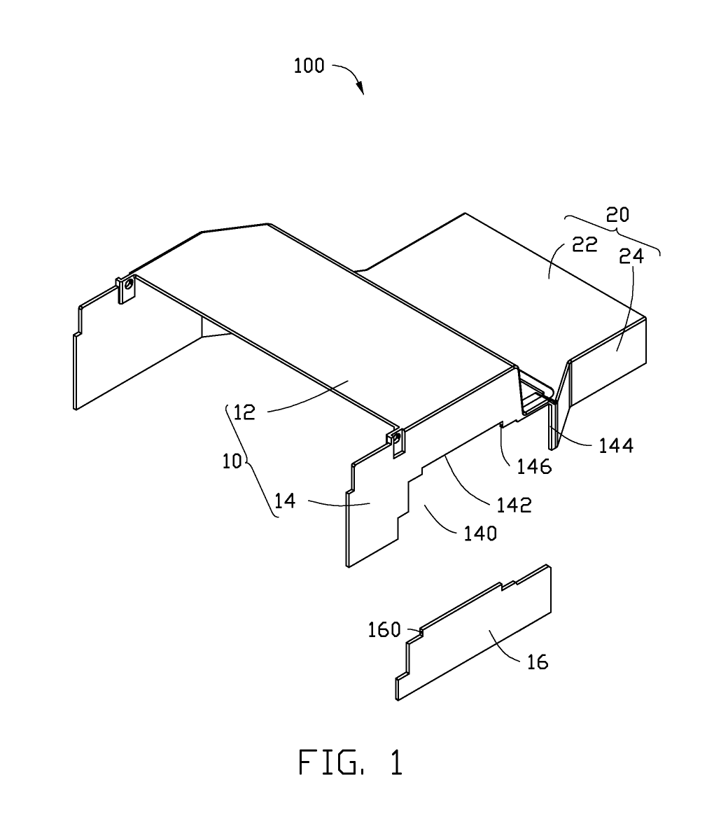

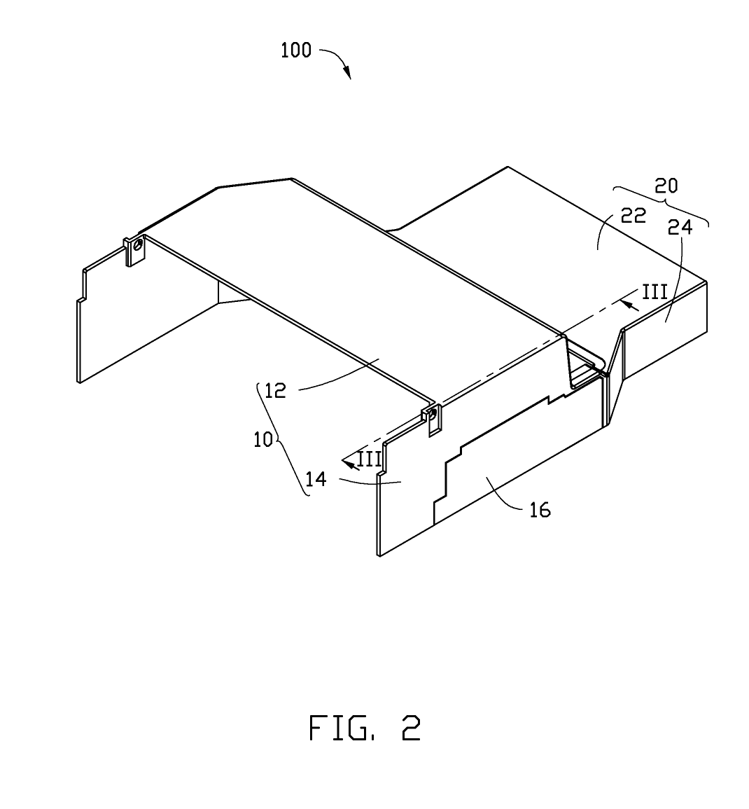

Referring to FIG. 1 and FIG. 2, an air duct 100 arranged on a motherboard(not shown) includes a first duct 10 and a second duct 20 connected to the first duct 10.

The first duct 10 includes a first top wall 12, two first sidewalls 14 extending substantially perpendicularly down from opposite sides of the first top wall 12, respectively, and a side cover 16. The second duct 20 is connected to a rear side of the first duct 10 and includes a second top wall 22 and two second sidewalls 24 extending down from opposite sides of the second top wall 22, respectively. The two second sidewalls 24 are connected to the corresponding first sidewalls 14. The second top wall 22 is lower than and substantially parallel to the first top wall 12.

One of the first sidewalls 14 defines an cutout 140 extending through a bottom side of the first sidewall 14. The cutout 140 includes a top edge 142 and two side edges 144. Each side edge 144 defines a receiving hole 146.

A shape of the side cover 16 matches a shape of the cutout 140. Two pins 160 extend from opposite side edges of an upper portion of the side cover 16, respectively.

In assembly, the side cover 16 is received in the cutout 140, such that the pins 160 are rotatably received in the receiving holes 146. Therefore, the side cover 16 is rotatably installed to the first sidewall 14 of the first duct 10.

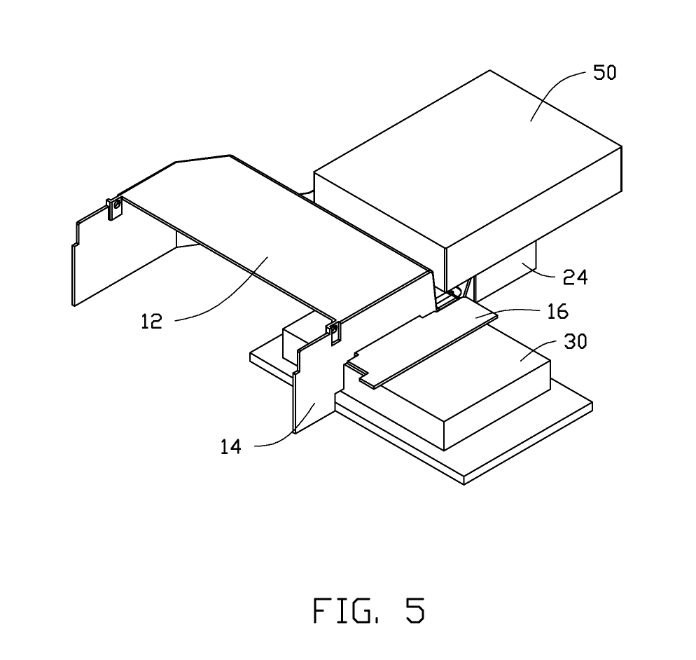

Referring to FIG. 5, if an electronic element 30 needs to be accommodated in the cutout 140 of the air duct 100, the side cover 16 is rotated to allow the electronic element 30 to be received in the cutout 140, and surface of the side cover 16 rests on a top surface of the electronic element 30. When the electronic element 30 is not received in the cutout 140, the side cover 16 is rotated back to block the cutout 140 to prevent air from leaking out of the air duct 100. Since the second top wall 22 of the second duct 20 is lower than the first top wall 12, another electronic element 50 can be set on the second top wall 22 of the second duct 20. Therefore, the electronic element 50 is located higher than other components of the mother board to avoid interfering with the outer components.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An air duct, comprising:
a first duct comprising a first top wall, two first sidewalls extending down from opposite sides of the first top wall, and a side cover, one of the first sidewalls defining an cutout in a bottom portion thereof, the side cover movably installed to the one first sidewall to cover or uncover the cutout.

2. The air duct of claim 1, wherein two pins extend out from opposite ends of an upper portion of the side cover, the cutout comprises a top edge and two side edges, each side edge defines a receiving hole, the pins are each rotatably received in a corresponding one of the receiving holes to rotatably mount the side cover to the one first sidewall.

3. The air duct of claim 1, further comprising a second duct connected to a rear end of the first duct.

4. The air duct of claim 3, wherein the second duct comprises a second top wall lower than and parallel to the first top wall, and two second sidewalls extending down from opposite sides of the second top wall and connected to the corresponding first sidewalls.
